(19) United States
(12) Patent Application Publication
(10) Pub. No.: US 2015/0362842 A1
(43) Pub. Date: Dec. 17, 2015

(54) LITHOGRAPHY APPARATUS, AND METHOD OF MANUFACTURING ARTICLE

(71) Applicant: CANON KABUSHIKI KAISHA, Tokyo (JP)

(72) Inventors: Shigeki Ogawa, Utsunomiya-shi (JP); Hideki Ina, Tokyo (JP)

(21) Appl. No.: 14/736,435

(22) Filed: Jun. 11, 2015

(30) Foreign Application Priority Data
Jun. 12, 2014 (JP) 2014-121841
Mar. 16, 2015 (JP) 2015-052686

(51) Int. Cl. G03F 7/20; G03F 7/26; G03F 7/16

(52) U.S. Cl. CPC G03F 7/70058; G03F 7/16; G03F 7/26

(57) ABSTRACT

The present invention provides a lithography apparatus which sequentially irradiates, with a beam, a first region and a second region, that have a stitching region in common, on a substrate to form a pattern on the substrate, the apparatus including a processor configured to respectively give weights to first information of a position of the second region before irradiation of the first region with a beam and second information of a position of the second region after the irradiation to obtain information of a position of the second region.

### BACKGROUND OF THE INVENTION

1. Field of the Invention

The present invention relates to a lithography apparatus, and a method of manufacturing an article.

2. Description of the Related Art

As a lithography apparatus for manufacturing an article such as a semiconductor device, for example, an apparatus which forms a pattern on a substrate using a beam such as an electron beam or an ion beam is known. In the apparatus, a stitching method of dividing one shot region into a plurality of regions, irradiating each of the plurality of regions obtained by the division with a beam to form a pattern, and forming a pattern by connecting the patterns together is known.

In the stitching method, stitching precision of connecting the patterns between the regions together is important. Therefore, a shift in positions where the patterns are drawn in the respective regions becomes a problem. To solve this, Japanese Patent No. 4468752 discloses a technique of ensuring stitching precision by setting a region where drawing regions overlap with each other (multiple drawing region) and controlling a drawing pattern based on the relationship between each region and the drawing pattern.

Note that in the stitching method, heat generated when drawing the pattern in each region may have an influence on a region where a pattern will be drawn next. Such an influence by heat appears as a change (a change in at least one of the position, dimension, and shape) of the pattern that has already been formed on the substrate.

On the other hand, an existing semiconductor exposure apparatus generally adopts global alignment for substrate alignment. In global alignment, a process (for example, regression calculation using a regression equation) is performed on the detection result of an alignment mark provided in a global shot region on the substrate, thereby determining the array (for example, the position) of the respective shot regions. Then, a substrate stage is driven based on the array to position the respective shot regions for exposure.

However, overlay precision may decrease due to the above-described influence by heat even if global alignment is performed.

Alignment (zone alignment) of detecting an alignment mark provided in a local shot region on the substrate and positioning the shot region based on the detection result can also be considered. Performing zone alignment can reduce the above-described influence by heat. However, it has become clear from an examination by the present inventor that performing zone alignment alone is not enough.

For example, while zone alignment is advantageous in terms of overlay precision, it can be disadvantageous in terms of stitching precision. If stitching precision decreases, line width precision (also referred to as CD (Critical Dimension) precision) may also decrease.

As described above, if zone alignment is performed, overlay precision can be improved but stitching precision can decrease. On the other hand, if global alignment is performed, stitching precision does not decrease but overlay precision cannot be improved.

### SUMMARY OF THE INVENTION

The present invention provides, for example, a lithography apparatus advantageous in overlay precision and stitching precision.

According to one aspect of the present invention, there is provided a lithography apparatus which sequentially irradiates, with a beam, a first region and a second region, that have a stitching region in common, on a substrate to form a pattern on the substrate, the apparatus including a processor configured to respectively give weights to first information of a position of the second region before irradiation of the first region with a beam and second information of a position of the second region after the irradiation to obtain information of a position of the second region.

Further aspects of the present invention will become apparent from the following description of exemplary embodiments with reference to the attached drawings.

### BRIEF DESCRIPTION OF THE DRAWINGS

FIG. 1 is a schematic view showing the arrangement of a drawing apparatus according to an aspect of the present invention.

FIGS. 2A and 2B are views for explaining the influence of an array change by heat in a stitching method.

FIGS. 3A and 3B are views for explaining the influence of the array change by heat in the stitching method.

FIG. 4 shows views for explaining the influence of the array change by heat in the stitching method.

FIG. 5 is a flowchart for explaining a drawing process in a drawing apparatus shown in FIG. 1.

FIG. 6 is a view for explaining global alignment measurement.

FIGS. 7A and 7B are views for explaining zone alignment measurement.

FIG. 8 is a flowchart for explaining the drawing process in the drawing apparatus shown in FIG. 1.

### DESCRIPTION OF THE EMBODIMENTS

Preferred embodiments of the present invention will be described below with reference to the accompanying drawings. Note that the same reference numerals denote the same members throughout the drawings, and a repetitive description thereof will not be given.

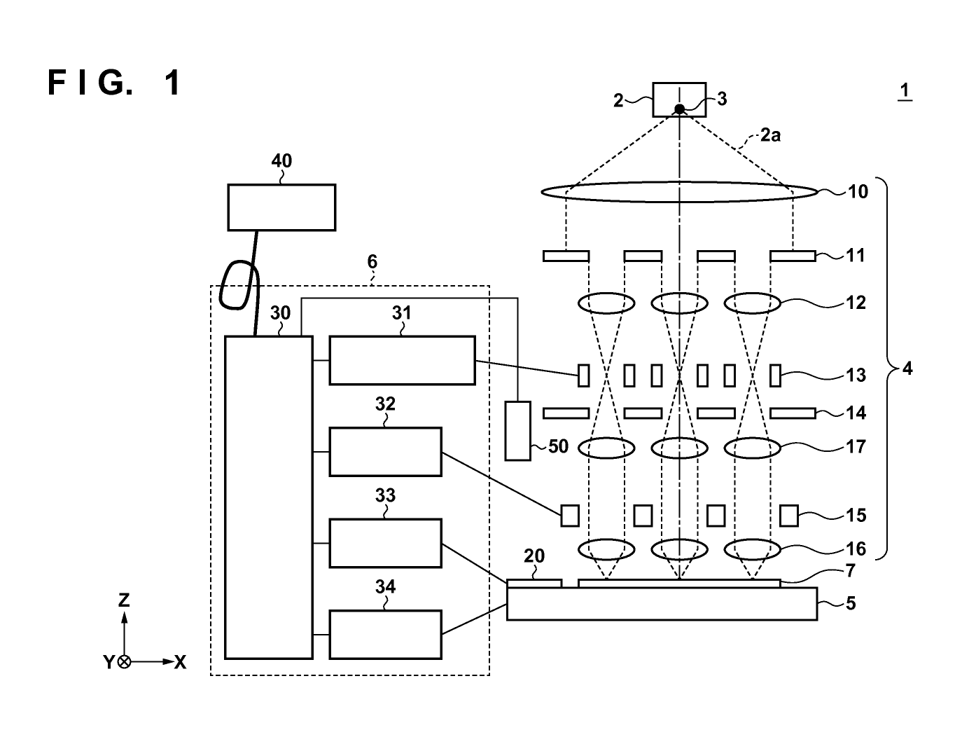

FIG. 1 is a schematic view showing the arrangement of a drawing apparatus 1 according to an aspect of the present invention. The drawing apparatus 1 is a lithography apparatus which forms a pattern on a substrate. The drawing apparatus 1 is a multibeam drawing apparatus which ON/OFF-controls irradiation with a plurality of beams separately to draw a predetermined pattern in a predetermined position on the substrate while deflecting the beams. The drawing apparatus 1 adopts a stitching method of sequentially irradiating, with the beams, the first region and the second region on the substrate which share a region (stitching region) where drawing regions overlap with each other, thereby forming the pattern.

In this embodiment, the beams are electron beams. However, they may be other charged particle beams such as ion beams. Furthermore, the drawing apparatus 1 may be a light beam (laser beam) drawing apparatus which performs drawing by diffracting (controlling) a light beam by an acoustic optical modulator.

As shown in FIG. 1, the drawing apparatus 1 includes an electron gun 2, an optical system 4 which divides, deflects, and focuses an electron beam emitted from a crossover 3 of the electron gun 2 into a plurality of electron beams, and a substrate stage 5 which holds a substrate 7. The drawing apparatus 1 also includes a control unit 6 which controls the whole (that is, the operations of respective components and the like) of the drawing apparatus 1, a detection unit 20, a setting unit (console) 40, and an alignment system 50. In the following description, the Z-axis is adopted as an electron beam irradiation direction with respect to the substrate, and the X-axis and the Y-axis are adopted as directions which are perpendicular to each other in a plane perpendicular to the Z-axis.

Since an electron beam attenuates rapidly in the atmosphere, and in order to prevent discharge caused by a high voltage, the components of the drawing apparatus 1 except for the control unit 6 and the setting unit 40 are arranged in a space where an internal pressure is regulated by an evacuation system. For example, the electron gun 2 and the optical system 4 are arranged in an electron-optical lens barrel where a high vacuum degree is maintained, and the substrate stage 5 is arranged in a chamber where a vacuum degree is maintained to be lower than that in the electron-optical lens barrel. The substrate 7 is a wafer made of, for example, single-crystal silicon and a photosensitive resist is applied onto its surface.

The electron gun 2 emits an electron beam by application of heat or an electric field. In FIG. 1, an electron beam (its orbit) 2a emitted from the crossover 3 is indicated by dotted lines. The optical system 4 includes, in order from an electron-gun side, a collimator lens 10, an aperture array 11, a first electrostatic lens array 12, a blanking deflector array 13, a blanking aperture array 14, a deflector array 15, and a second electrostatic lens array 16. The optical system 4 may also include a third electrostatic lens array 17 on the downstream side of the blanking aperture array 14.

The collimator lens 10 is formed by an electromagnetic lens and forms the electron beam emitted from the crossover 3 into an almost parallel beam. The aperture array 11 has a plurality of circular openings arrayed in a matrix and divides the electron beam from the collimator lens 10 into the plurality of electron beams. The first electrostatic lens array 12 is formed by three electrode plates having circular openings and focuses the electron beams with respect to the blanking aperture array 14.

The blanking deflector array 13 and the blanking aperture array 14 are arranged in a matrix shape and control the ON (non-blanking)/OFF (blanking) operations of irradiation with each electron beam. The deflector array (deflectors) 15 deflects images on the substrate 7 held on the substrate stage 5 in the X-axis direction. The second electrostatic lens array 16 focuses the electron beams that have passed through the blanking aperture array 14 on the substrate 7. Further, the second electrostatic lens array 16 focuses the images of the crossover 3 with respect to the detection unit 20 arranged on the substrate stage 5.

The substrate stage 5 has an arrangement capable of six-axis driving, and moves the substrate 7 in at least two axial directions of the X-axis direction and the Y-axis direction while holding it by vacuum chuck or the like. An interferometer (laser length measuring device) or the like measures the position of the substrate stage 5 in real time. The resolution of the interferometer (that is, the driving precision of the substrate stage 5) is, for example, about 0.1 nm.

The detection unit 20 configured to detect the characteristics of the electron beams which irradiate the substrate 7 is arranged on the substrate stage 5. The output signal (electrical signal) of the detection unit 20 is used to detect the characteristics of (the changes in) the electron beams. Note that the characteristics of the electron beams include, for example, the positions, shapes, and intensities (intensity distributions) of the electron beams. Any arrangement known in the art can be applied to the detection unit 20. However, the detection unit 20 uses, for example, a slit to detect the above-described characteristics of the electron beams.

The control unit 6 includes, in order to control the operation of each component related to a drawing process of the drawing apparatus 1, a main control unit 30, a lens control unit (not shown), a blanking control unit 31, a deflection control unit 32, a detection control unit 33, and a stage control unit 34. The main control unit 30 generally controls the lens control unit, the blanking control unit 31, the deflection control unit 32, the detection control unit 33, and the stage control unit 34.

The lens control unit controls the respective operations of the collimator lens 10, the first electrostatic lens array 12, the second electrostatic lens array 16, and the third electrostatic lens array 17. The blanking control unit 31 controls the operation of the blanking deflector array 13 based on a blanking signal generated by a drawing pattern generation unit, a bitmap conversion unit, and a blanking command generation unit. A drawing pattern generation circuit generates a drawing pattern which is converted into bitmap data by the bitmap conversion unit. The blanking command generation unit generates a blanking signal based on the bitmap data. The deflection control unit 32 controls the operation of the deflector array 15 based on a deflection signal generated by a deflection signal generation unit.

The detection control unit 33 determines the presence/absence of electron beam irradiation based on the output signal of the detection unit 20 and inputs the determination result to the main control unit 30. Furthermore, the detection control unit 33 cooperates with the stage control unit 34 and the deflection control unit 32 via the main control unit 30 to obtain the characteristics of the electron beam (the position, shape, and intensity of the electron beam) which irradiate the substrate 7. More specifically, the detection control unit 33 obtains the characteristics of the electron beam based on the output signal of the detection unit 20, information of a position of the substrate stage 5 from the stage control unit 34, and the deflection amount (deflection width) of the electron beams from the deflection control unit 32.

The stage control unit 34 obtains the target position of the substrate stage 5 based on a command from the main control unit 30 and controls the movement of the substrate stage 5 to position it in the target position. The position of the substrate stage 5 measured by the interferometer (measurement data obtained by the interferometer) is used to control the movement of the substrate stage 5.

The stage control unit 34 continuously scans the substrate stage 5 (substrate 7) in the Y-axis direction during drawing of the pattern. At this time, the deflector array 15 deflects the electron beam which irradiates the substrate 7 in the X-axis direction using, as a reference, the position of the substrate stage 5 measured by the interferometer. The blanking deflector array 13 performs the ON/OFF operation of electron beam irradiation so as to obtain a target dose (target irradiation amount) on the substrate.

The alignment system 50 serves as a detection unit which detects a mark on the substrate. The alignment system 50 is used for, for example, global alignment, zone alignment, or die-by-die alignment and detects an alignment mark provided in each of a plurality of regions on the substrate. The alignment mark is drawn in a scribe line on the substrate simultaneously with a pattern drawn in a real element region on the substrate. Furthermore, the alignment system 50 can also detect, instead of the alignment mark drawn in the scribe line, a part of the pattern drawn in the real element region or the like as an alignment mark.

The main control unit 30 has a function of generally managing the lens control unit, the blanking control unit 31, the deflection control unit 32, the detection control unit 33, and the stage control unit 34 as described above and controlling the whole (operation) of the drawing apparatus 1. Furthermore, the main control unit 30 determines a position (drawing position) where a pattern is formed in alignment of the substrate 7, as will be described later. At this time, the main control unit 30 functions as a processor which gives a weight to each of the first information of a position in the second region on the substrate before irradiating the first region on the substrate with a beam and the second information of a position in the second region after irradiating the first region with a beam, and obtains information of a position in the second region. Note that the first region and the second region on the substrate share the stitching region, as described above.

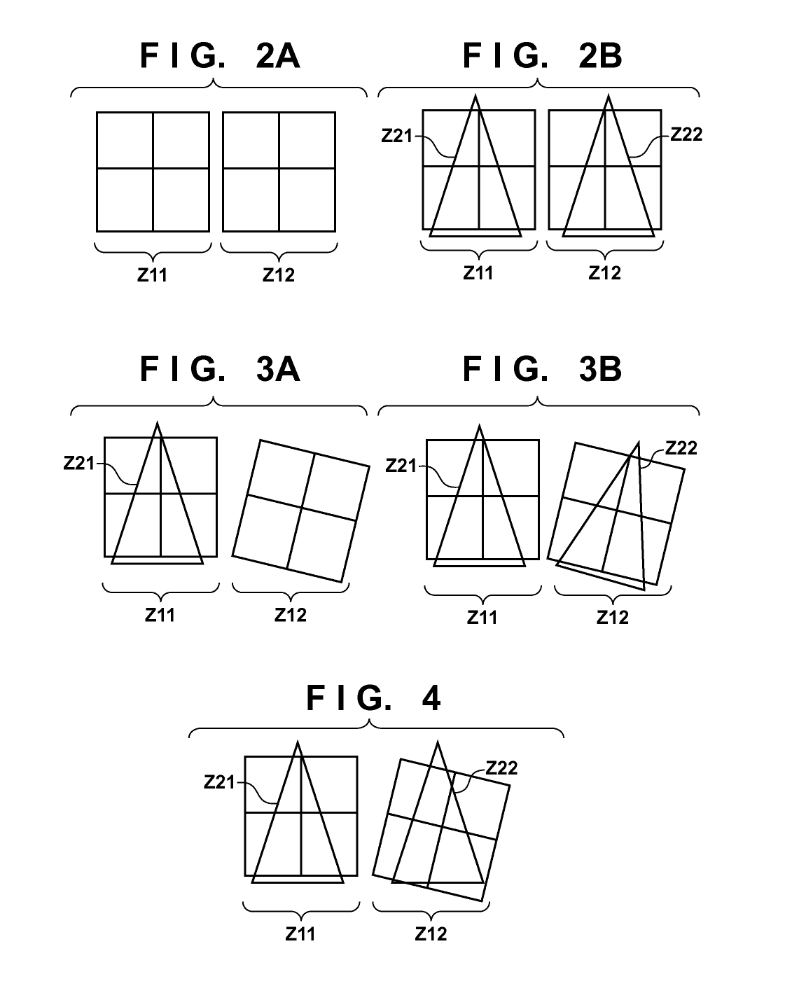

The influence of an array change by heat when drawing a pattern (partial pattern) in a region on the substrate in the stitching method will now be described in detail with reference to FIGS. 2A, 2B, 3A, 3B, and 4. In FIGS. 2A, 2B, 3A, 3B, and 4, each of first partial patterns Z11 and Z12 that have already been formed in the first region and the second region on the substrate is represented by a rectangle. Each of second partial patterns Z21 and Z22 which will be drawn in the first region and the second region is represented by a triangle. Note that each of these shapes does not represent the shape of each partial pattern to be actually drawn. Furthermore, the first partial pattern Z11 and the first partial pattern Z12 are illustrated separately from each other for the sake of simplicity. In practice, however, the first partial pattern Z11 and the first partial pattern Z12 are adjacent to each other and form a continuous pattern by stitching. The same also applies to the second partial pattern Z21 and the second partial pattern Z22.

FIG. 2A shows a state in which the first partial pattern Z11 and the first partial pattern Z12 are drawn in the first region and the second region on the substrate which are adjacent to each other, and more particularly, an ideal state in which the first partial pattern Z11 and the first partial pattern Z12 are adjacent to each other correctly. FIG. 2B shows a state in which the second partial pattern Z21 is drawn with being overlaid on the first partial pattern Z11 and the second partial pattern Z22 is drawn with being overlaid on the first partial pattern Z12. Assume that zone alignment is performed from drawing of the second partial pattern Z21 until drawing of the second partial pattern Z22. At this time, if the state includes neither influence by heat when drawing the second partial pattern Z21 nor shift in the position of the first partial pattern Z12 (shift in the drawing position), an ideal state shown in FIG. 2B is obtained. In other words, the second partial patterns Z21 and Z22 are drawn correctly with being overlaid on the first partial patterns Z11 and Z12, respectively.

In practice, however, the array change occurs due to the influence by heat when drawing the second partial pattern Z21 overlaid on the first partial pattern Z11 and the position of the first partial pattern Z12 changes (the first partial pattern Z12 is rotated), as shown in FIG. 3A. By performing zone alignment from drawing of the second partial pattern Z21 until drawing of the second partial pattern Z22, it is possible to correctly draw the second partial pattern Z22 overlaid on the first partial pattern Z12, as shown in FIG. 3B. On the other hand, in FIG. 3B, the second partial pattern Z21 and the second partial pattern Z22 do not form a continuous pattern (that is, form a discontinuous pattern), decreasing stitching precision (line width (CD) precision).

If the second partial pattern Z22 is drawn without performing zone alignment (or without reflecting a zone alignment result) from drawing of the second partial pattern Z21 until drawing of the second partial pattern Z22, a state shown in FIG. 4 is obtained. In FIG. 4, the second partial pattern Z21 and the second partial pattern Z22 form the continuous pattern, and thus causing no decrease in stitching precision. It is impossible, however, to correctly draw the second partial pattern Z22 overlaid on the first partial pattern Z12, decreasing overlay precision.

As described above, it is difficult, in the stitching method, to set both overlay precision and stitching precision to optimal states owing to the influence of the array change by heat when drawing the pattern in the region on the substrate. In other words, overlay precision and stitching precision has a contradictory relationship, making it difficult to achieve both of them.

Overlay precision and stitching precision required for pattern formation change depending on a semiconductor device and a manufacturing process thereof. Therefore, overlay precision and stitching precision are corrected separately, a result different from a result desired by a user may be obtained (that is, overlay precision and stitching precision required for pattern formation cannot be satisfied).

To cope with this, the drawing apparatus 1 according to this embodiment allows a user to arbitrarily input (control) a condition of prioritizing overlay precision or stitching precision, a condition of putting the same degree of priority on both overlay precision and stitching precision, or the like. More specifically, the drawing apparatus 1 includes the setting unit 40 which sets, in accordance with the user input, the value of an order parameter indicating a priority between overlay precision and stitching precision, and the value of a weighted parameter indicating the weight given to each of overlay and stitching. The drawing apparatus 1 performs drawing in accordance with the values of the order parameter and the weighted parameter set by the setting unit 40, thereby ensuring the result desired by the user, that is, overlay precision and stitching precision required for pattern formation.

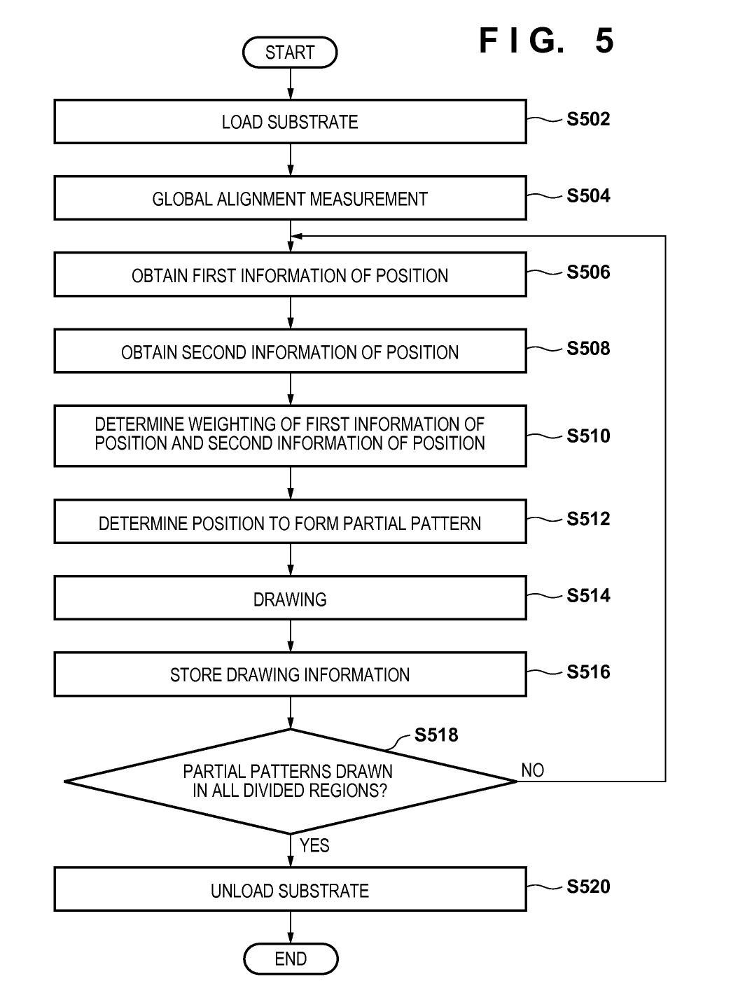

The drawing process by the stitching method in the drawing apparatus 1 will be described with reference to FIG. 5. As described above, the drawing process is performed by causing the control unit 6, and in particular the main control unit 30 to generally control the respective units of the drawing apparatus 1. Assume that one shot region on the substrate is divided into a plurality of divided regions and the partial pattern is drawn in each divided region.

In step S502, the substrate 7 is loaded into the drawing apparatus 1 from outside the drawing apparatus 1 and held by the substrate stage 5. The substrate 7 loaded into the drawing apparatus 1 is coated in advance with a resist required to draw the patterns. Furthermore, an underlying pattern (circuit pattern) and an alignment mark have already been formed on the substrate 7 loaded into the drawing apparatus 1.

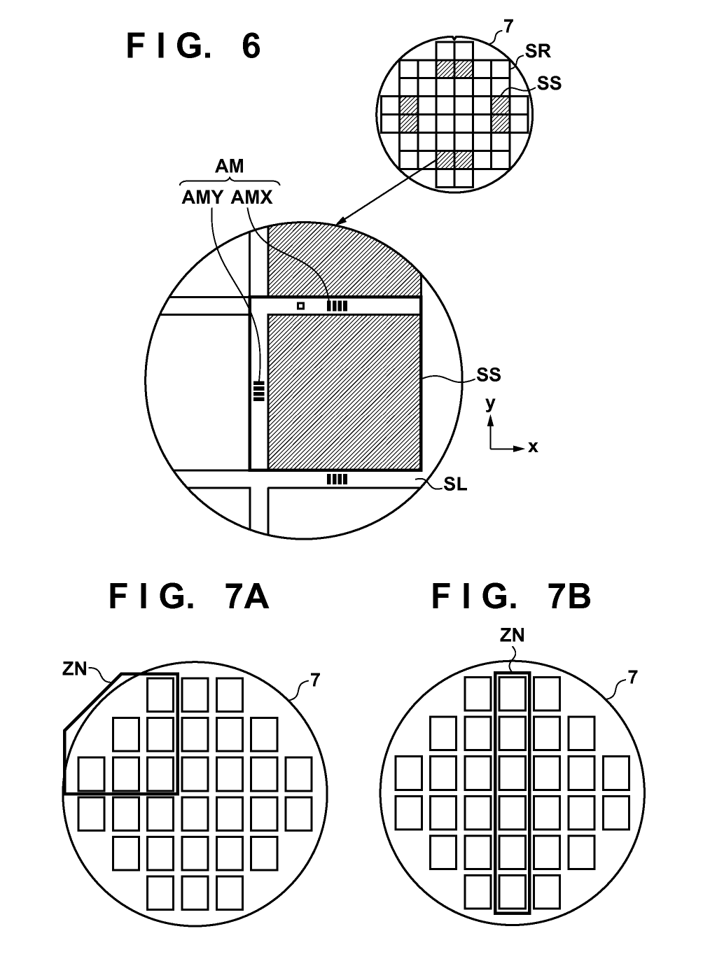

In step S504, global alignment measurement is performed to obtain the array (position) of the shot region on the substrate. In global alignment measurement, first, the alignment system 50 detects an alignment mark AM provided in each global sample shot region (specific sample region) SS out of a plurality of shot regions SR on the substrate 7, as shown in FIG. 6. Then, the process (such as regression calculation using the regression expression) is performed on the detection result of the alignment system 50, thereby obtaining the array of the respective shot regions SR on the substrate. Each alignment mark AM includes, for example, an X measurement mark AMX and a Y measurement mark AMY formed in a scribe line SL. The advantage of global alignment measurement is that the positions of all the shot regions SR on the substrate can be obtained in a short time and the influence of an error caused by a shape error in the alignment marks AM is small. However, global alignment measurement also has a drawback of reducing overlay precision if each shot region has a positional shift (drawing positional shift).

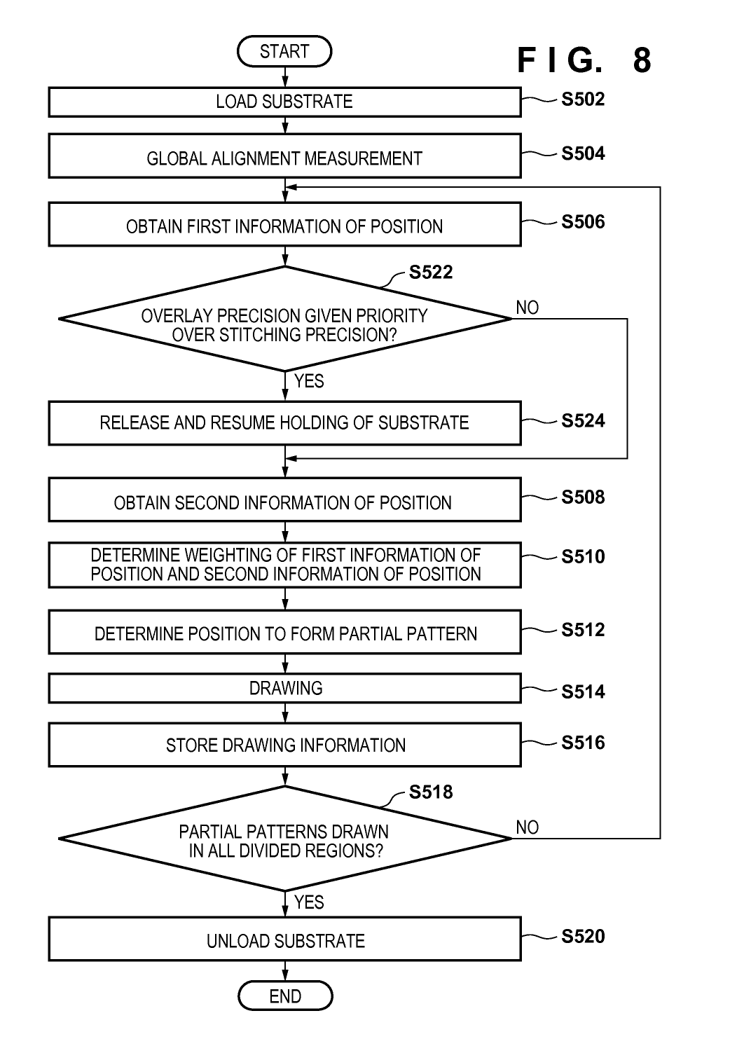

In step S506, the first information of the position for forming the partial pattern is obtained for a target divided region (second region), out of the plurality of divided regions on the substrate, targeted for drawing the partial pattern. The first information of the position indicates the position of the target divided region before irradiating a region (first region) adjacent to the target divided region on the substrate with the beam, and more particularly, a drawing position where stitching precision has priority. Further, the first information of the position includes information on at least one of the translation, rotation, shape, and dimension of the target divided region before irradiating the region adjacent to the target divided region on the substrate with the beam. The first information of the position can be obtained from the array of the shot regions on the substrate obtained in global alignment measurement in step S504. The first information of the position may also be obtained from a result of zone alignment measurement or die-by-die alignment measurement performed when forming the underlying pattern in the target divided region. At this time, for example, drawing information obtained by drawing the underlying pattern is used. For example, the drawing information is stored in a storage unit such as a memory of the control unit 6, and includes the accumulated irradiation amount of the electron beam which irradiates the substrate 7 when drawing the underlying pattern, a linear correction amount such as a shift, a magnification, or a rotation when drawing, and the position of the substrate stage 5. As described above, the first information of the position is obtained based on a procedure of any one of global alignment, zone alignment, and die-by-die alignment. Note that in zone alignment measurement, the alignment system 50 detects the alignment mark provided in the local shot region on the substrate. For example, as shown in FIGS. 7A and 7B, the alignment system 50 detects alignment marks provided in a zone ZN including the target divided region and a region around the target divided region grouped together with the target divided region. The zone ZN is determined to have an arbitrary shape depending on the position of a next target divided region. The shape of the zone ZN is not limited to those shown in FIGS. 7A and 7B. On the other hand, in die-by-die alignment measurement, the alignment system 50 detects an alignment mark provided in the target divided region.

In step S508, the alignment system 50 detects the alignment mark that has already been formed in the target divided region, and the second information of the position for forming the partial pattern is obtained based on the detection result. The second information of the position indicates the position of the target divided region after irradiating the region (first region) adjacent to the target divided region on the substrate with the beam, and more particularly, a drawing position where overlay precision has priority. Further, similarly to the first information of the position, the second information of the position includes information on at least one of the translation, rotation, shape, and dimension of the target divided region after irradiating the region adjacent to the target divided region on the substrate with the beam. The second information of the position is obtained using zone alignment measurement or die-by-die alignment measurement. With zone alignment measurement or die-by-die alignment measurement, it is possible to measure the array change by heat in immediately preceding drawing and prevent a decrease in overlay precision by performing drawing based on the second information of the position.

In step S510, the value of the order parameter and the value of the weighted parameter set by the setting unit 40 are obtained, and the weight (weighting) given to each of the first information of the position and the second information of the position is determined in accordance with the obtained values. The order parameter includes a variable indicating priority of overlay precision or stitching precision. For example, in a case in which the variable of the order parameter is “1”, priority is given to stitching precision, and the weight given to the first information of the position is set to “1” and the weighting given to the second information of the position is set to “0”. In a case in which the variable of the order parameter is “0”, priority is given to overlay precision, and the weight given to the first information of the position is set to “0” and the weight given to the second information of the position is set to “1”. On the other hand, the weighted parameter includes the first variable (first weight) indicating the weight given to the first information of the position and the second variable (second weight) indicating the weight given to the second information of the position. Note that each of the first variable and the second variable of the weighted parameter is a real number from 0 (inclusive) to 1 (inclusive), and the sum of the first variable and the second variable is 1. Therefore, in a case in which the first variable is “1” and the second variable is “0”, priority is given to stitching precision, and in a case in which the first variable is “0” and the second variable is “1”, priority is given to overlay precision. In a case other than those, for example, in a case in which the first variable is “0.3” and the second variable is “0.7”, each of stitching precision and overlay precision is considered in a 3:7 ratio.

In step S512, for the target divided region, a position to form the partial pattern is determined. More specifically, the weight determined in step S510 is given to each of the first information of the position obtained in step S506 and the second information of the position obtained in step S508, and the position to form the partial pattern is determined based on the first information of the position and the second information of the position to which the weights have been given.

In step S514, the partial pattern is drawn in the target divided region based on the position determined in step S512. In step S516, drawing information when drawing the partial pattern in a partial divided region in step S514 (for example, the accumulated irradiation amount of the electron beam which irradiates the substrate 7, the linear correction amount such as the shift, the magnification, or the rotation when drawing, and the position of the substrate stage 5) is stored in, for example, the storage unit such as the memory of the control unit 6. The drawing information stored in step S516 is used as needed when obtaining the first information of the position (step S506).

In step S518, it is determined whether the partial patterns have been drawn in all the divided regions on the substrate. If the partial patterns have not been drawn in all the divided regions on the substrate, the process advances to step S506, in which the first information of the position for forming the partial pattern is obtained by setting the divided region where no partial pattern has been drawn to the target divided region. On the other hand, if the partial patterns have been drawn in all the divided regions on the substrate, the process advances to step S520, in which the substrate 7 is unloaded outside the drawing apparatus 1.

As described above, the drawing apparatus 1 can set the parameters which determine the priority between overlay precision and stitching precision for each substrate or lot thereof. Therefore, the drawing apparatus 1 can implement the lithography apparatus advantageous in achieving both overlay precision and stitching precision required for pattern formation.

In this embodiment, the case in which the drawing apparatus 1 is the multibeam drawing apparatus has been described as an example. However, the same effect can also be obtained even if the drawing apparatus 1 is a single-beam drawing apparatus. Furthermore, in this embodiment, the parameters which determine the priority between overlay precision and stitching precision are fixed for one substrate. However, they may not be fixed for one substrate or the lot thereof (that is, they may be varied for the substrate or the lot thereof).

The drawing apparatus 1 targets a case in which a global alignment measurement result and the result of zone alignment measurement or die-by-die alignment measurement are different from each other owing to the influence of the array change by heat when drawing the pattern in the region on the substrate. Factors for the difference between the global alignment measurement result and the result of zone alignment measurement or die-by-die alignment measurement include, for example, the following three factors including the array change in drawing target regions by heat. Note that the array change can be a change related to at least one of the translation, rotation, shape, and dimension of each region.

Factor 1: a shift in an ideal grid array (X-Y coordinates) by the substrate stage between the preceding process and the current process (the difference in the positioning error of the substrate stage between two layers of pattern formation targets)
Factor 2: the array change by the influence of heat owing to pattern drawing
Factor 3: the asymmetry of the alignment mark

The difference between factor 2, and factor 1 and factor 3 is that whether it is generated by drawing the substrate. In factor 2, a part of the substrate is distorted locally due to the influence by heat when drawing the pattern, thereby generating the array change. It is therefore possible to distinguish between factor 2 and factor 1 or factor 3 as a result of detecting the alignment mark on the substrate without drawing the pattern. If, for example, the alignment mark on the substrate is detected without drawing the pattern and its grid array is different from the grid array after drawing, it is possible to determine factor 2.

Factor 1 and factor 3 have the same grid array after drawing, and thus need to be determined by another method. The alignment mark can be detected by, for example, rotating the substrate by 90° or 180°. In factor 3, the asymmetry of the shape of the alignment mark becomes a factor for an error in the grid array. Therefore, if the substrate is rotated, the error in the grid array is also rotated. This makes it possible to distinguish between factor 1 and factor 3. Note that if the asymmetry distribution of the shape of the alignment mark is symmetrical about polar coordinates in the center of the substrate, it is impossible to distinguish between factor 1 and factor 3 even if the substrate is rotated. In practice, however, the asymmetry distribution of the shape of the alignment mark hardly becomes symmetrical about the polar coordinates in the center of the substrate. Therefore, rotating the substrate is effective at distinguishing between factor 1 and factor 3.

Furthermore, the above-described three factors are generated simultaneously, in practice. It is therefore necessary to distinguish between the array change by heat when drawing the pattern (factor 2), and the difference between the global alignment measurement result and the result of zone alignment measurement or die-by-die alignment measurement. By the above-described method of distinguishing between factor 1 and factor 3, a value different between the global alignment measurement result and the result of zone alignment measurement or die-by-die alignment measurement is obtained quantitatively and saved as a table. Then, it is also possible to cope with a case in which the above-described three factors are generated simultaneously by using the table at the time of actual drawing. That is, the influence of factor 1 and factor 3 on an overlay error can be reduced.

Note that the drawing process by the stitching method in the drawing apparatus 1 is not limited to the process shown in FIG. 5 but can also be replaced by, for example, a process shown in FIG. 8. As compared with the process shown in FIG. 5, the process shown in FIG. 8 is the same for steps S502 to S520, but new processes (steps S522 and S524) are performed between steps S506 and S508. The processes in steps S522 and S524 will be described below. In step S502, the substrate stage 5 holds the substrate 7 by vacuum chuck (an electrostatic force or electrostatic chucking), as described above.

In step S522, reference is made to the value of the order parameter and the value of the weighted parameter set by the setting unit 40 so as to determine whether to prioritize overlay precision over stitching precision. For example, it is determined, in the weighted parameter, whether the second variable (second weight) indicating the weight given to the second information of the position is larger than the first variable (first weight) indicating the weight given to the first information of the position. If overlay precision does not have priority, that is, stitching precision has priority, the process advances to step S508. On the other hand, if overlay precision has priority, the process advances to step S524.

In step S524, holding (chucking) of the substrate 7 by the substrate stage 5 is released and then resumed after the release. Holding of the substrate 7 by the substrate stage 5 is released temporarily before obtaining the second information of the position (step S508), as described above, thereby releasing a stress accumulated in the substrate 7 by heat (exposure heat) when drawing the pattern. This makes it possible to alleviate nonlinear deformation of the substrate 7 owing to the power relationship between the thermal deformation force of the substrate 7 by exposure heat and a holding force (frictional force) with respect to the substrate 7.

The drawing apparatus 1 is advantageous in performing overlay drawing on the substrate by the stitching method, and thus suitable for manufacturing an article, for example, a microdevice such as a semiconductor device or an element having a microstructure. A method of manufacturing the article includes a step of forming the pattern on a photoresist applied to a substrate using the drawing apparatus 1 (step of performing drawing on the substrate) and a step of processing (developing) the substrate, on which the pattern has been formed, in the preceding step. This manufacturing method can further include other known steps (oxidation, deposition, vapor deposition, doping, planarization, etching, resist peeling, dicing, bonding, packaging, and the like). The method of manufacturing the article according to this embodiment is advantageous in at least one of the performance, quality, productivity, and production cost of the article, as compared to a conventional method.

The present invention does not limit the lithography apparatus to the drawing apparatus but can also be applied to the exposure apparatus. Note that the exposure apparatus serves as the lithography apparatus which exposures the substrate, using a beam such as light or charged particles, via a reticle or a mask and a projection optical system. Furthermore, the present invention can also apply the plurality of divided regions on the substrate as the plurality of shot regions on the substrate.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application Nos. 2014-121841 filed Jun. 12, 2014, and 2015-052686 filed Mar. 16, 2015, which are hereby incorporated by reference herein in their entirety.

What is claimed is:

1. A lithography apparatus which sequentially irradiates, with a beam, a first region and a second region, that have a stitching region in common, on a substrate to form a pattern on the substrate, the apparatus comprising:
a processor configured to respectively give weights to first information of a position of the second region before irradiation of the first region with a beam and second information of a position of the second region after the irradiation to obtain information of a position of the second region.

2. The apparatus according to claim 1, further comprising a detector configured to detect a mark on the substrate,
wherein the first information and the second information are respectively obtained based on outputs from the detector.

3. The apparatus according to claim 1, further comprising a setting device configured to set, in accordance with an input thereto, the weights respectively given to the first information and the second information.

4. The apparatus according to claim 3, wherein the setting device configured to set a first weight given to the first information and a second weight given to the second information.

5. The apparatus according to claim 4, wherein each of the first weight and the second weight is a real number not smaller than 0 and not greater than 1, and a sum of the first weight and the second weight is 1.

6. The apparatus according to claim 1, wherein the processor is configured to obtain the first information based on a procedure of any one of global alignment, zone alignment, and die-by-die alignment.

7. The apparatus according to claim 1, wherein the processor is configured to obtain the second information based on a procedure of any one of zone alignment and die-by-die alignment.

8. The apparatus according to claim 1, wherein each of the first information and the second information includes information on a translation, a rotation, a shape, or a dimension or any two thereof or any three thereof or all thereof of the second region.

9. The apparatus according to claim 4, wherein the setting device configured to set the first weight and the second weight in accordance with an input of stitching precision or overlay precision or both thereof.

10. The apparatus according to claim 1, wherein the beam includes a charged particle beam.

11. The apparatus according to claim 1, further comprising a stage configured to hold the substrate,
wherein the processor is configured to, if a second weight given to the second information is larger than a first weight given to the first information, before the second information is obtained, perform release of holding of the substrate by the stage and holding of the substrate by the stage after the release.

12. A method of manufacturing an article, the method comprising steps of:
forming a pattern on a substrate using a lithography apparatus; and
processing the substrate, on which the pattern has been formed, to manufacture the article,
wherein the lithography apparatus sequentially irradiates, with a beam, a first region and a second region, that have a stitching region in common, on a substrate to form a pattern on the substrate, and includes:
a processor configured to respectively give weights to first information of a position of the second region before irradiation of the first region with a beam and second information of a position of the second region after the irradiation to obtain information of a position of the second region.
